(19) United States
(12) Patent Application Publication
(10) Pub. No.: US 2012/0154021 A1
(43) Pub. Date: Jun. 21, 2012

(54) INTEGRATED CIRCUIT AND METHOD OF FABRICATING SAME

(76) Inventors: Amita Chandrakant Patil, Albany, NY (US); Vinayak Tilak, Niskayuna, NY (US); Naresh Kesavan Rao, Clifton Park, NY (US)

(21) Appl. No.: 12/973,200

(22) Filed: Dec. 20, 2010

(51) Int. Cl. H03K 3/01

(52) U.S. Cl. 327/534

(57) ABSTRACT

A method includes providing a wide bandgap semiconductor substrate that includes a first transistor and a second transistor defined thereon. The method also includes coupling the first transistor to the second transistor. The method further includes coupling a bias circuit to the first transistor and the second transistor and forming a junction therebetween. The method also includes coupling the first transistor to a first voltage source and coupling the second transistor to a second voltage source. The first voltage source and the second voltage source are configured to define a predetermined differential input voltage.

### BACKGROUND

The subject matter described herein relates generally to integrated circuits and, more particularly, to methods and apparatus for fabricating integrated circuits for high-temperature environments.

At least some known silicon (Si) digital integrated circuits include a plurality of cascaded logic/sequential circuits, where each circuit includes at least one driver, or pull-down device and at least one load device, or pull-up device. A pull-up device is a device that energizes either itself and/or a downstream component to a positive voltage. In contrast, a pull-down device is a device that energizes either itself and/or a downstream component to a negative voltage, or a ground voltage potential. Typically active devices, such as an n-channel metal oxide semiconductor field effect transistor, commonly referred to as nMOSFET, or, as used herein, nMOS is used as driver device. nMOS, or its p-channel counterpart, pMOS, or a passive resistor is used as pull-up device. Due to low-hole mobility and fabrication challenges, only n-channel transistors may be used in wide bandgap semiconductor materials, such as silicon carbide (SiC). The active driver device is typically in one of two predetermined states, i.e., either “off” or “on”, thereby facilitating binary logic operation. Each device has a predetermined threshold voltage (V_{TH}) that defines the minimum voltage that changes the state of the device from “off” to “on” to conduct current therethrough. For example, the V_{TH} of an enhancement-mode Si nMOS device in modern technologies is positive, typically in a range of few hundred millivolts.

When an input to the driver device is below the V_{TH} of the driver device, the driver is turned “off” and the associated output is a binary logic “high”. In contrast, when the input to the driver device is higher than the associated V_{TH}, the output is pulled-down by the driver device to a binary logic “low”. The binary logic “high” and “low” are relative terms and a range of their associated values is at least partially defined by power supply voltages and the type of driver devices and pull-down devices used.

Transistors, including MOS devices, are temperature sensitive. As temperature increases, the V_{TH} decreases, approaching zero volts at a predetermined high temperature and becoming negative at higher temperatures. In particular, SiC MOS devices may experience large V_{TH} shifts with associated temperature changes. Under such conditions, the binary logic “low” value can be above the V_{TH} of the driver device, therefore unable to turn “off” the driver device, and the binary functionality of the integrated circuit may be compromised.

Many Si digital integrated circuits with cascaded logic/sequential circuits are used in known industrial applications. Many of these applications have varying environmental conditions that may include significant temperature variations. Anticipation of such varying temperatures may impose restrictive constraints on the industrial applications in which such known integrated circuits are used. Typically, these known integrated circuits are limited to operating temperatures of approximately 175 degrees Celsius (° C.) (347 degrees Fahrenheit (° F.)). Many industrial applications include environments with temperatures ranging from about −55° C. (−67° F.) to about 300° C. (572° F.), and above 300° C. for extended periods of time. Some known Si integrated circuits are cooled by known heat removal methods. These methods are typically useful for only short-term high-temperature excursions. The size, weight, and costs of the methods are often prohibitive. Also, some known Si integrated circuits are maintained a distance away from the high-temperature environments. Such distances may require extended cable lengths between the integrated circuits and the associated industrial devices, which increases costs of operations and may adversely affect reliability of operations due to unforeseen cable failures.

### BRIEF DESCRIPTION

In one aspect, a method includes providing a wide bandgap semiconductor substrate that includes a first transistor and a second transistor defined thereon. The method also includes coupling the first transistor to the second transistor. The method further includes coupling a bias circuit to the first transistor and the second transistor and forming a junction therebetween. The method also includes coupling the first transistor to a first voltage source and coupling the second transistor to a second voltage source. The first voltage source and the second voltage source are configured to define a predetermined differential input voltage.

In another aspect, a device includes a wide bandgap semiconductor substrate. The device also includes a first transistor defined on the substrate and a first voltage source coupled to the first transistor. The device further includes a second transistor defined on the substrate and a second voltage source coupled to the second transistor. The first transistor is coupled to the second transistor. The device also includes a bias circuit coupled to the first transistor and the second transistor. The first voltage source and the second voltage source are configured to define a predetermined differential input voltage.

In yet another aspect, an apparatus includes a plurality of devices. The devices include a wide bandgap semiconductor substrate. The devices also include a first transistor defined on the substrate and a first voltage source coupled to the first transistor. The devices further include a second transistor defined on the substrate and a second voltage source coupled to the second transistor. The first transistor is coupled to the second transistor. The devices also include a bias circuit coupled to the first transistor and the second transistor. The first voltage source and the second voltage source are configured to define a predetermined differential input voltage.

### BRIEF DESCRIPTION OF THE DRAWINGS

These and other features, aspects, and advantages of the presently described embodiments will become better understood when the following detailed description is read with reference to the accompanying drawings in which like characters represent like parts throughout the drawings, wherein:

FIG. 1 is a schematic view of a prior art cascaded inverter using enhancement mode nMOS;

FIG. 2 is a schematic view of an example nMOS-based inverter using an exemplary architecture;

FIG. 3 is a schematic view of an example nMOS-based data latch (Dlatch) circuit using the exemplary architecture shown in FIG. 2;

FIG. 4 is a graphical view of operation of the data latch shown in FIG. 3 at room temperature;

FIG. 5 is a graphical view of operation of the data latch shown in FIG. 3 at 300° C. (572° F.); and

FIG. 6 is a flow chart illustrating an example method that may be used in fabricating the integrated circuit shown in FIGS. 2 and 3.

### DETAILED DESCRIPTION

In the following specification and the claims, which follow, reference will be made to a number of terms, which shall be defined to have the following meanings

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

The example integrated circuits and methods described herein may overcome disadvantages of known silicon (Si) integrated circuits by using a robust circuit architecture in silicon carbide (SiC) or other suitable wide bandgap technology such as gallium nitride (GaN), aluminum nitride (AlN), indium nitride (InN), and other alloys thereof. The circuit architecture facilitates applying a predetermined, substantially constant, small differential input voltage (±ΔVᵢₙ) between each of at least two driver devices. Also, the circuit architecture facilitates applying a predetermined bias current to the circuit. This current may be chosen to be several orders of magnitude higher than the maximum anticipated leakage current at high temperatures. Depending on the polarity of the applied the bias current is steered in one of the two differential branches. Since the source node of the driver devices acts like an incremental ground, it is able to track changes in threshold voltage (V_{TH}) such that the integrated circuit retains binary functionality at elevated temperatures, even as V_{TH} approaches 0V, or attains a negative value. Therefore, the example integrated circuits exhibit robust circuit performance when embedded within apparatus that may be exposed to wide range of temperatures. Examples of such high-temperature apparatus include high-temperature tools and equipment for exploration of deep oil wells in conditions in excess of 175 degrees Celsius (° C.) (347 degrees Fahrenheit (° F.)), including temperatures up to, and in excess of 300° C. (572° F.) for extended periods of time.

In addition to high-temperature applications, the robust circuit architecture facilitates increasing functionality of the associated integrated circuits in applications that include a wider tolerance to process-driven variations in transistor parameters. The robust circuit architecture provides a speed advantage over some known Si digital integrated circuits that do not use the robust circuit architecture since any node in a given circuit does not need to accommodate large voltage variations. Further, the robust circuit architecture provides complementary circuit functionality with little to no additional die area, thereby with little to no additional costs. Moreover, the robust circuit architecture facilitates maintaining a substantially constant, predetermined, non-zero, static power consumption during binary switching. Thus, the associated integrated circuits do not generate switching noise.

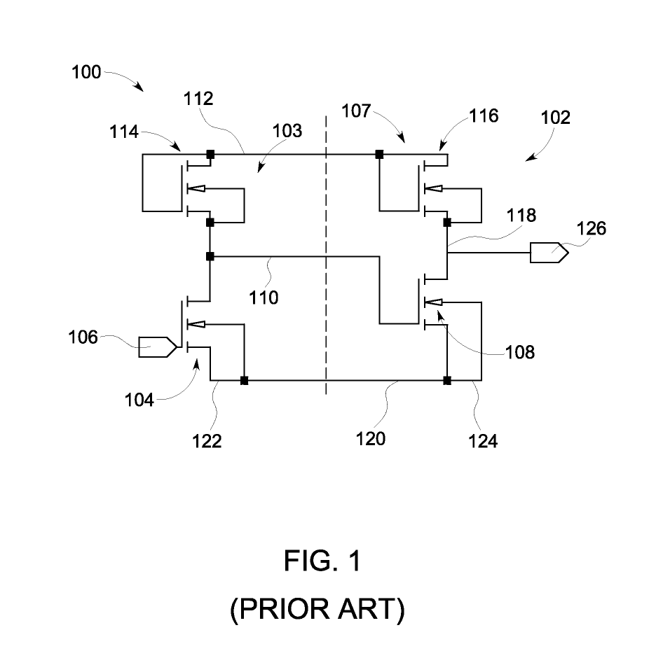

FIG. 1 is a schematic view of an integrated circuit 100. Integrated circuit 100 is a cascaded inverter device using enhancement mode nMOS, and is ground-referenced as described further below. Integrated circuit 100 may be fabricated on a silicon (Si) or wide band gap semiconductor, such as a SiC substrate, referred to as substrate 102. Integrated circuit 100 includes a first inverter 103 that includes an nMOS driver device 104 coupled to an input connection 106. Integrated circuit 100 further includes a second inverter 107 that includes an nMOS driven device 108. Driver device 104 is coupled to driven device 108 via a first output conduit 110. Driver device 104 drives driven device 108. Integrated circuit 100 also includes a positive voltage, or V_{DD} supply bus 112. First inverter 103 further includes a first diode-connected nMOS load device 114, and second inverter 107 includes a second diode-connected nMOS load device 116. Both diode-connected nMOS load devices 114 and 116 are coupled to V_{DD} supply bus 112. Driven device 108 is coupled to nMOS load device 116 via a second output conduit 118. Driver device 104 is coupled to nMOS load device 114 via first output conduit 110. Integrated circuit 100 further includes a ground bus 120. Driver device 104 is coupled to ground bus 120 via a first source connection 122. Driven device 108 is coupled to ground bus 120 via a second source connection 124. Ground bus 120 is maintained at approximately ground potential, or 0V. Integrated circuit 100 further includes an output connection 126 coupled to second output conduit 118.

When the input voltage at driver input connection 106 is below the threshold voltage (V_{TH}) of driver device 104, driver device 104 is “off”, and first output conduit 110 is energized to a high voltage defined as approximately the voltage potential of V_{DD} supply bus 112 minus the small voltage drop across first diode-connected nMOS load device 114 (due to a leakage current of nMOS device 104). When the high voltage potential of first output conduit 110 exceeds the V_{TH} of driven device 108, driven device 108 is “on” and acts as a pull-down device and second diode-connected nMOS load device 116 acts as a pull-up device. Second output conduit 118 is pulled-down to a logic “low” level defined by the relative strength of device 116 and device 108. Lowest logic “low” voltage in this topology is approximately 0V.

As the temperature of base 102 increases, the V_{TH} of devices 104 and 108 decrease, approaching approximately 0V, and attaining negative values at higher temperatures. Under such conditions, the logic “low” voltage level is above the V_{TH} of device 108, and the binary functionality of integrated circuit 100 may be compromised.

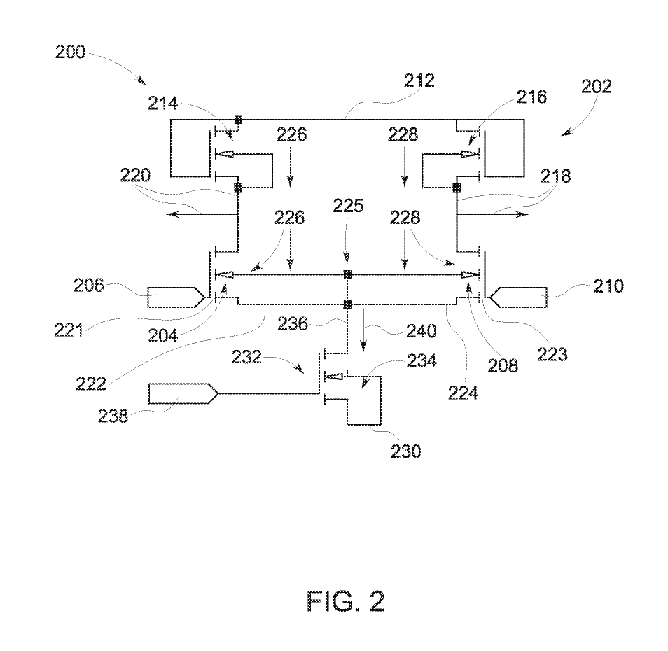

FIG. 2 is a schematic view of an example device, e.g., an integrated circuit 200. In the example embodiment, integrated circuit 200 is an inverter using a robust, nMOS-based circuit architecture as described further below. Integrated circuit 200 includes a silicon carbide (SiC) substrate, or base 202. Alternatively, base 202 is formed from materials that include, without limitation, gallium nitride (GaN), aluminum nitride (AlN), indium nitride (InN), and other alloys thereof. Integrated circuit 200 also includes a first transistor, e.g., a first nMOS device 204 coupled to a first input connection 206. First nMOS device 204 has a threshold voltage of V_{TH1}. Integrated circuit 200 further includes a second transistor, e.g., a second nMOS device 208 that is coupled to a second input connection 210. Second nMOS device 208 has a threshold voltage of V_{TH2}. In the example embodiment, V_{TT1} and V_{TH2} are each in a range of approximately +2V to approximately +5V at approximately room temperature, i.e., 25° C. (77° F.). As environmental temperatures increase, V_{TH1} and V_{TH2} decrease. Integrated circuit 200 also includes a positive voltage, or V_{DD} supply bus 212, that is energized to a potential within a range of approximately 10V to approximately 20V.

Integrated circuit 200 further includes a first diode-connected nMOS device 214 and a second diode-connected nMOS device 216. Both nMOS devices 214 and 216 are coupled to V_{DD} supply bus 212. Second nMOS device 208 is coupled to second diode-connected nMOS device 216 via a first output conduit 218. First nMOS device 204 is coupled to first diode-connected nMOS device 214 via a second output conduit 220. First nMOS device 204 is coupled to a first source connection 222 via a first source terminal, or node 221. Second nMOS device 208 is coupled to a second source connection 224 via a second source terminal, or node 223. Moreover, in the exemplary embodiment, first source connection 222 is coupled to second source connection 224. A bulk connection 225 is coupled to source connections 222 and 224. Alternatively, bulk connection 225 is coupled to any connections other than source connections 222 and 224 that enable operation of integrated circuit 200 as described herein.

Also, in the example embodiment, integrated circuit 200 includes a bias circuit 232. Bias circuit 232 includes a bias transistor 234. Bias circuit 232 also includes a bias junction 236. Bias circuit 232 further includes a bias voltage connection 238 that transmits a bias voltage V_{bias}. V_{bias} is predetermined, and varies, such that a bias current I_{bias} to ground bus 230, as shown by current arrow 240, is substantially constant. Integrated circuit 200 also includes a ground bus 230 that is maintained at approximately ground potential, or 0V.

In the example embodiment, first nMOS device 204, first diode-connected nMOS device 214, and second output conduit 220 form first circuit branch 226. Second nMOS device 208, second diode-connected nMOS device 216, and first output conduit 218 form a second half circuit branch 228. Alternatively, integrated circuit 200 includes any number of circuit branches that enables operation of integrated circuit 200 as described herein.

Also, in the example embodiment, by applying a differential voltage ΔV₁₋₂ to inputs 206 and 210, bias current I_{bias} 240 is steered in either one of circuit branches 226 and 228. By reversing the polarity of the differential voltage ΔV₁₋₂, bias current I_{bias} 240 is steered in the other circuit branch 228 or 226.

Since a first source node 242 of first nMOS device 204 and a second source node 244 of second nMOS device 208 behave in a manner similar to an incremental ground, they facilitate tracking changes in the associated threshold voltages (V_{TH}) and the integrated circuit 200 retains binary functionality at elevated temperatures, even as V_{TH} approaches 0V, and subsequently attains negative values. Therefore, example integrated circuit 200 exhibits robust circuit performance when embedded within apparatus that may be exposed to elevated temperatures.

In the example embodiment, in addition to extended high-temperature applications up to, and above 300° C. (572° F.), the circuit architecture as described herein for integrated circuit 200 facilitates increasing functionality of integrated circuit 200 in industrial applications that include routine or periodic operational temperature variations in temperatures between −55° C. (−67° F.) and 300° C. (572° F.), and above 300° C.

Further, in the example embodiment, the circuit architecture as described herein facilitates applying predetermined bias current I_{bias} 240 to integrated circuit 200 that may be chosen to be several orders of magnitude higher than a predetermined high-temperature leakage current, thereby increasing robustness of circuit due to failures occurring from increased leakage currents.

Also, in the example embodiment, the circuit architecture as described herein may consume more power than integrated circuit 100 due to constant current flow through the circuit, thereby possibly facilitating an increase in operational costs. The power consumption is approximately equal to constant bias current I_{bias} 240 multiplied by V_{DD} supply bus 212 voltage, regardless of whether the current flow is through first circuit branch 226 or second circuit branch 228. However, any increase in operating costs may be offset by circuit reliability and the substantially constant, predetermined, non-zero, static power consumption during binary switching operations of integrated circuit 200 facilitates significantly reducing generated electronic switching noise.

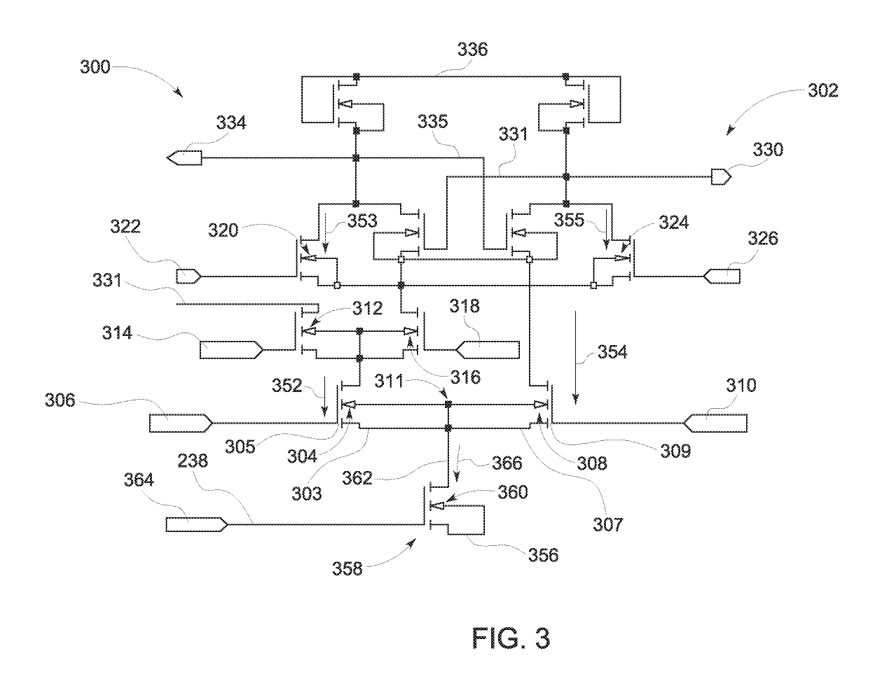

FIG. 3 is a schematic view of an example of a data latch apparatus, or Dlatch integrated circuit 300 using a circuit architecture similar to that used for integrated circuit 200 (shown in FIG. 2). Moreover, in the example embodiment, integrated circuit 300 is a clocked Dlatch with reset. Integrated circuit 300 includes a SiC substrate, or base 302. Alternatively, base 302 is formed from materials that include, without limitation, gallium nitride (GaN), aluminum nitride (AlN), indium nitride (InN), and other alloys thereof. Integrated circuit 300 also includes a first clock transistor, e.g., an nMOS device, or CLK device 304 that is coupled to a first clock voltage input, or CLK connection 306. CLK device 304 has a threshold voltage of V_{TH-CLK}. Integrated circuit 300 further includes a second clock transistor, e.g., an nMOS device, or CLKB device 308 that is coupled to a second clock voltage input, or CLKB connection 310. CLKB device 308 has a threshold voltage of V_{TH-CLKB}.

CLK device 304 is coupled to a first source connection 303 via a first source terminal, or node 305. CLKB device 308 is coupled to a second source connection 307 via a second source terminal, or node 309. Moreover, in the exemplary embodiment, first source connection 303 is coupled to second source connection 307. A bulk connection 311 is coupled to source connections 303 and 307. Alternatively, bulk connection 311 is coupled to any connections other than source connections 303 and 307 that enable operation of integrated circuit 300 as described herein.

Integrated circuit 300 also includes a first reset transistor, e.g., an nMOS device, or RESET device 312 that is coupled to a first reset voltage input, or RESET connection 314. RESET device 312 has a threshold voltage of V_{TH-RESET}. Integrated circuit 300 further includes a second reset transistor, e.g., an nMOS device, or RESETB device 316 that is coupled to a second reset voltage input, or RESETB connection 318. RESETB device 316 has a threshold voltage of V_{TH-RESETB}. Integrated circuit 300 also includes a first data transistor, e.g., an nMOS device, or D device 320 that is coupled to a first data voltage input, or D connection 322. D device 320 has a threshold voltage of V_{TH-D}. Integrated circuit 300 further includes a second data transistor, e.g., an nMOS device, or DB device 324 that is coupled to a second data voltage input, or DB connection 326. DB device 324 has a threshold voltage of V_{TH-DB}.

In the example embodiment, V_{TH-CLK}, V_{TH-CLKB}, V_{TR-RESET}, V_{TH-RESETB}, V_{TH-D1} and V_{TH-D2} are each in a range of approximately +2V to approximately +5V at approximately room temperature, i.e., 25° C. (77° F.). V_{TH-D1} and V_{TH-D2} decrease to approximately 0V, and subsequently below 0V as environmental temperatures increase to, and exceed, approximately 300° C. (572° F.). Such temperatures may increase up to approximately 300° C. for extended periods of time.

Integrated circuit 300 further includes a first data output, or Q connection 330, that is coupled to a first data output, or Q conduit 331. Integrated circuit 300 also includes a second data output, or QB connection 334, coupled to a second data output, or QB conduit 335.

In the example embodiment, integrated circuit 300 also includes a positive voltage, or V_{DD} supply bus 336. Also, in the example embodiment, integrated circuit 300 includes a ground bus 356 that is maintained at approximately ground potential, or 0V. Also, in the example embodiment, RESETB device 316 and CLK device 304 at least partially form a first circuit branch 352, and CLKB device 308 at least partially forms a second circuit branch 354. Further, in the exemplary embodiment, integrated circuit 300 includes a third circuit branch 353 and a fourth circuit branch 355.

Integrated circuit 300 further includes a bias circuit 358. Bias circuit 358 includes a bias transistor 360. Bias circuit 358 also includes a bias junction 364. Bias circuit 358 further includes a bias voltage connection 364 that transmits with a bias voltage V_{bias}. V_{bias} is predetermined, and varies, such that a bias current I_{bias} to ground bus 356, as shown by current arrow 366, is substantially constant.

By applying a differential voltage (ΔV_{CLK-CLKB}) to CLK connection 306 and CLKB connection 310, bias current I_{bias} 366 is steered entirely in either one of branches 352 and 354. By reversing the polarity of the differential voltage (ΔV_{CLK-CLKB}), bias current I_{bias} 366 is steered in the other branch 354 or 352. Thus, Dlatch integrated circuit 300 as described above changes state on a positive CLK edge. The Dlatch can be reset (i.e. output Q is “low”, and QB is “high”) by applying a positive differential voltage (+ΔV_{CLK-CLKB}) to RESET connection 314 and RESETB connection 318.

During normal operation, a negative differential voltage (−ΔV_{CLK-CLKB}) is applied to RESET connection 314 and RESETB connection 318. Depending on the polarity of the differential input (ΔV_{CLK-CLKB}) applied to D connection 322 and DB connection 326, bias current I_{bias} 366 is steered to either one of branches 353 and 355, and Q connection 330 follows D connection 322 at positive CLK edge. QB is the complementary output of the Dlatch.

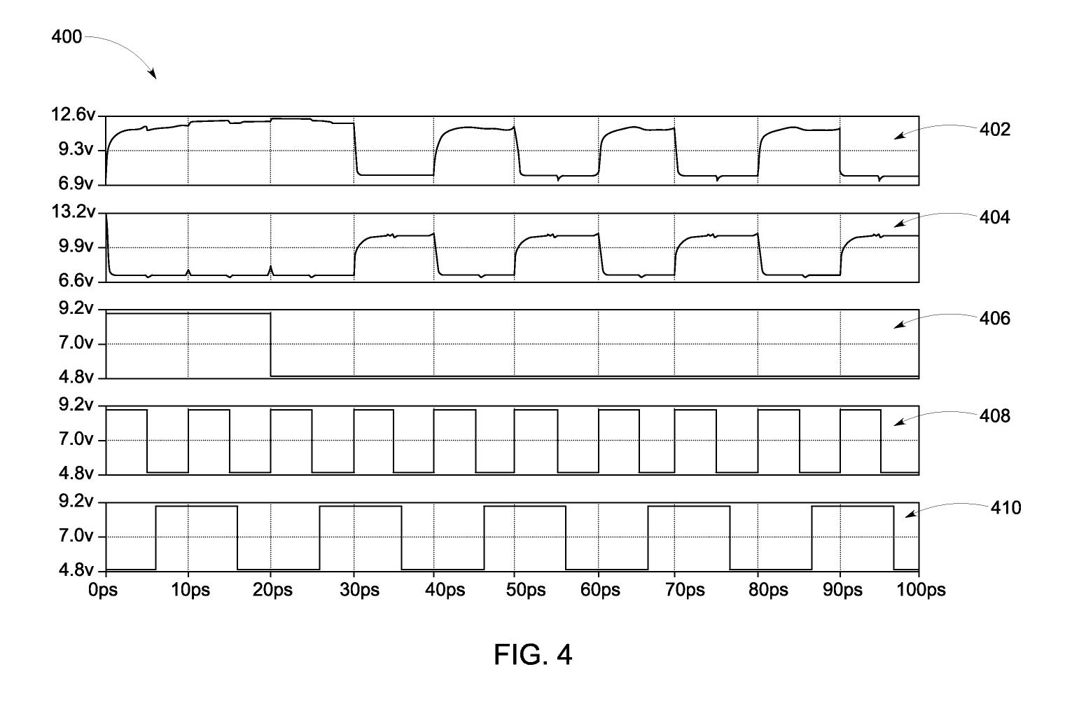

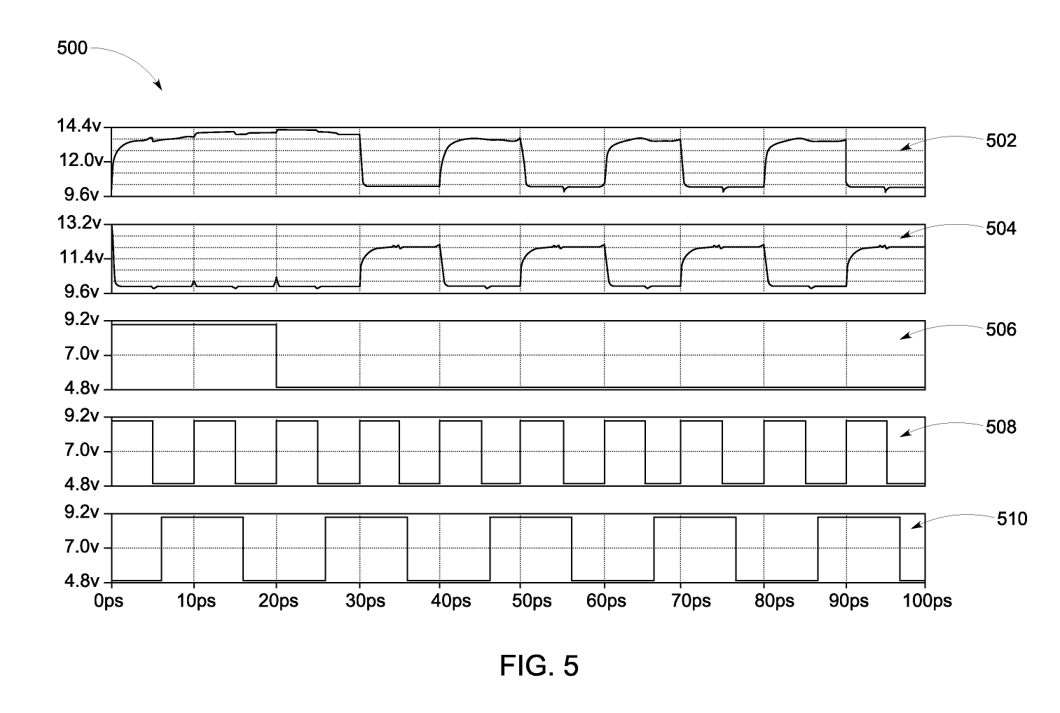

FIG. 4 is a graphical view 400 of operation of Dlatch integrated circuit 300 (shown in FIG. 3) at approximately room temperature, i.e., 25° C. (77° F.). Graph 400 includes a graph 402 of V_{QB} as a function of time. Graph 400 also includes a graph 404 of V_{Q} as a function of time. Graph 400 further includes a graph 406 of V_{RESET} as a function of time. Graph 400 also includes a graph 408 of V_{CLK} as a function of time. Graph 400 further includes a graph 410 of V_{D} as a function of time. FIG. 5 is a graphical view 500 of operation of Dlatch integrated circuit 300 (shown in FIG. 3) at approximately 300° C. (572° F.). Graph 500 includes a graph 502 of V_{QB} as a function of time. Graph 500 also includes a graph 504 of V_{Q} as a function of time. Graph 500 further includes a graph 506 of V_{RESET1} as a function of time. time. Graph 500 also includes a graph 508 of V_{CLK1} as a function of time. Graph 500 further includes a graph 510 of V_{D} as a function of time. In the example embodiment, the circuit architecture of integrated circuit 300 facilitates a substantially similarity between graphs 402 and 502, graphs 404 and 504, graphs 406 and 506, graphs 408 and 508, and graphs 410 and 510.

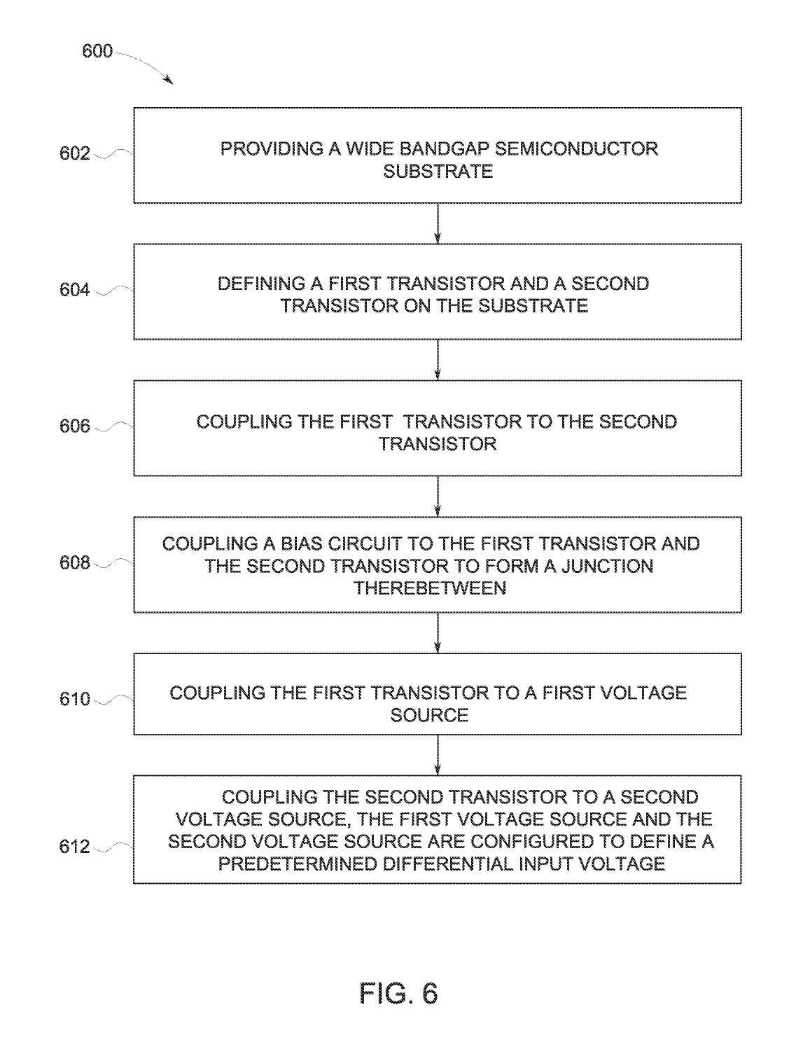

FIG. 6 is a flow chart illustrating an example method 600 that may be used in fabricating integrated circuit 200/300 (shown in FIGS. 2 and 3, respectively). In the example embodiment, a wide bandgap semiconductor substrate, e.g., silicon carbide (SiC) substrate 202/302 (shown in FIGS. 2 and 3, respectively) is provided 602. First MOS device 204/304 (shown in FIGS. 2 and 3, respectively) and second MOS device 208/308 (shown in FIGS. 2 and 3, respectively) are defined 604 on SiC substrate 202/302. First MOS device 204/304 is coupled 606 to second MOS device 208/308. Bias circuit 232/366 are coupled 608 to first MOS device 204/304 and second MOS device 208/308 to form junction 225/309 (shown in FIGS. 2 and 3, respectively) therebetween. First MOS device 204/304 is coupled 610 to first voltage source 206/306 (shown in FIGS. 2 and 3, respectively). Second MOS device 208/308 is coupled 612 to second voltage source 210/310 (shown in FIGS. 2 and 3, respectively). First voltage source 206/306 and second voltage source 210/310 are configured to define a predetermined differential input voltage, ΔV₁₋₂ and ΔV_{CLK-CLKB}, respectively.

The above-described integrated circuits and methods of fabrication may overcome disadvantages of known Si integrated circuits by using a robust circuit architecture on SiC or other suitable wide bandgap technology. The circuit architecture facilitates applying a predetermined, substantially constant, small differential input voltage (±ΔVin) to each of at least two driver devices. Also, the circuit architecture facilitates applying a predetermined bias current to the circuit; this current may be chosen to be several orders of magnitude higher than the maximum anticipated leakage current at high temperature. Depending on the polarity of the applied differential input voltage the bias current is completely steered in one of the two differential branches. Since the source node of the driver devices acts like an incremental ground, it is able to track changes in threshold voltage (V_{TH}) such that the integrated circuit retains binary functionality at elevated temperatures, even as V_{TH} approaches 0V or becomes negative. Therefore, the example integrated circuits exhibit robust circuit performance when embedded within apparatus that may be exposed to elevated temperatures. Also, in addition to high-temperature applications, the circuit architecture facilitates increasing functionality of the associated integrated circuits in applications that include a wider tolerance range for process variations. Further, use of such circuit architecture facilitates maintaining complementary circuit functionality with little to no additional die area, thereby with little to no additional costs. Moreover, the circuit architecture facilitates maintaining a substantially constant, predetermined, non-zero, static power consumption during binary switching, thus the associated integrated circuits do not generate switching noise. Furthermore, the circuit architecture provides a speed advantage thereby facilitating high-speed operation.

Example embodiments of integrated circuits and methods for fabricating such integrated circuits are described above in detail. The integrated circuits and fabrication methods are not limited to the specific embodiments described herein, but rather, components of integrated circuits and/or steps of the fabrication methods may be utilized independently and separately from other components and/or steps described herein. For example, the integrated circuits and methods may also be used in combination with other electronic devices and fabrication methods, and are not limited to practice with only the integrated circuits as described herein. Rather, the example embodiment can be implemented and utilized in connection with many other electronic system and fabrication applications.

Although specific features of various embodiments may be shown in some drawings and not in others, this is for convenience only. Moreover, references to “one embodiment” in the above description are not intended to be interpreted as excluding the existence of additional embodiments that also incorporate the recited features. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A method comprising:
providing a wide bandgap semiconductor substrate that includes a first transistor and a second transistor defined thereon;
coupling the first transistor to the second transistor;
coupling a bias circuit to the first transistor and the second transistor and forming a junction therebetween;
coupling the first transistor to a first voltage source; and
coupling the second transistor to a second voltage source,
wherein the first voltage source and the second voltage source are configured to define a predetermined differential input voltage.

2. A method in accordance with claim 1 further comprising:
defining the first transistor within a first circuit branch; and
defining the second transistor within a second circuit branch.

3. A method in accordance with claim 2 further comprising:
defining a plurality of transistors in the first circuit branch;
defining a plurality of transistors in the second circuit branch;
coupling at least one input source to at least one of the plurality of transistors; and
coupling an output device to at least one of the plurality of transistors.

4. A method in accordance with claim 2 further comprising configuring the bias circuit to facilitate transmission of an electric current through one of the first circuit branch and the second circuit branch as a function of the polarity of the predetermined differential input voltage.

5. A method in accordance with claim 4, wherein coupling a bias circuit to the first transistor and the second transistor comprises coupling a bias voltage source to the bias circuit, the bias voltage source configured to maintain the electric current substantially constant by varying a bias voltage input.

6. A method in accordance with claim 1 further comprising configuring the first voltage source and the second voltage source to define the predetermined differential input voltage to facilitate binary operation of the first transistor and the second transistor at temperatures within a range of −55° C. degrees Celsius (° C.) to 300° C.

7. A method in accordance with claim 1, wherein providing a wide bandgap semiconductor substrate comprises providing at least one of silicon carbide (SiC), gallium nitride (GaN), aluminum nitride (AlN), and indium nitride (InN).

8. A device comprising:
a wide bandgap semiconductor substrate;
a first transistor defined on said substrate and a first voltage source coupled to said first transistor;
a second transistor defined on said substrate and a second voltage source coupled to said second transistor, said first transistor coupled to said second transistor; and
a bias circuit coupled to said first transistor and said second transistor, wherein said first voltage source and said second voltage source are configured to define a predetermined differential input voltage.

9. A device in accordance with claim 8 further comprising:
a first circuit branch at least partially defined by said first transistor; and
a second circuit branch at least partially defined by said second transistor.

10. A device in accordance with claim 9, wherein said bias circuit configured to facilitate transmission of an electric current through one of said first circuit branch and said second circuit branch as a function of a polarity of the predetermined differential input voltage.

11. A device in accordance with claim 10, wherein said bias circuit comprises a bias voltage source, said bias voltage source configured to maintain the electric current substantially constant by varying a bias voltage input.

12. A device in accordance with claim 9 further comprising a plurality of transistors, wherein at least a one of said plurality of transistors is at least one of:
defined in the first circuit branch;
defined in the second circuit branch;
coupled to at least one input source; and
coupled to at least one output device.

13. A device in accordance with claim 8 further comprising a plurality of transistors, wherein at least one of said plurality of transistors is a driver transistor and at least one of said plurality of transistors is a driven transistor.

14. A device in accordance with claim 8, wherein said wide bandgap semiconductor substrate comprises at least one of silicon carbide (SiC), gallium nitride (GaN), aluminum nitride (AlN), and indium nitride (InN).

15. An apparatus comprising:
a plurality of devices comprising:
a wide bandgap semiconductor substrate;
a first transistor defined on said substrate and a first voltage source coupled to said first transistor;
a second transistor defined on said substrate and a second voltage source coupled to said second transistor, said first transistor coupled to said second transistor; and
a bias circuit coupled to said first transistor and said second transistor,
wherein said first voltage source and said second voltage source are configured to define a predetermined differential input voltage.

16. An apparatus in accordance with claim 15 further comprising:
a first circuit branch at least partially defined by said first transistor; and
a second circuit branch at least partially defined by said second transistor.

17. An apparatus in accordance with claim 16, wherein said bias circuit configured to facilitate transmission of an electric current through one of said first circuit branch and said second circuit branch as a function of a polarity of the predetermined differential input voltage.

18. An apparatus in accordance with claim 15, wherein said bias circuit comprises a bias voltage source, said bias voltage source configured to maintain the electric current substantially constant by varying a bias voltage input.

19. An apparatus in accordance with claim 16 further comprising a plurality of transistors, wherein at least a one of said plurality of transistors is at least one of:
defined in the first circuit branch;
defined in the second circuit branch;
coupled to at least one input source; and
coupled to at least one output device.

20. An apparatus in accordance with claim 15 further comprising a plurality of transistors, wherein at least one of said plurality of transistors is a driver transistor and at least one of said plurality of transistors is a driven transistor.
